(19) United States
(12) Patent Application Publication
(10) Pub. No.: US 2026/0353618 A1
(43) Pub. Date: Nov. 5, 2026

(54) ELECTRICAL APPLIANCE

(71) Applicant: SEW-EURODRIVE GMBH & CO. KG, Bruchsal (DE)

(72) Inventor: Horst FRANK, Öbstringen-Odenheim (DE)

(73) Assignee: SEW-EURODRIVE GMBH & CO. KG, Bruchsal (DE)

(21) Appl. No.: 19/484,596

(22) PCT Filed: Apr. 22, 2024
(86) PCT No.: PCT/EP2024/060973

§ 371 Date: Nov. 14, 2025

(30) Foreign Application Priority Data
May 16, 2023 (DE) 10 2023 002 004.4

(51) Int. Cl. H05K 7/20; H05K 7/14

(52) U.S. Cl. CPC H05K 7/209; H05K 7/1407; H05K 7/1432; H05K 7/20409

(57) ABSTRACT

An electrical appliance includes a circuit board which is populated with a heat-generating component, a heat sink having at least one cooling fin, and a housing part. A bushing is plugged into a recess in the cooling fin, a screw, the screw head of which presses the printed circuit board, together with the component, towards the heat sink, is screwed into an internal thread of the bushing, and the bushing has a polyhedral region which is pressed into the housing part.

### FIELD OF THE INVENTION

The present invention relates to an electrical appliance.

### BACKGROUND INFORMATION

In certain conventional systems, an electrical appliance has a heat-generating component, such as a power semiconductor, which is in contact with a heat sink for heat dissipation.

### SUMMARY

Example embodiments of the present invention provide an electrical appliance, in which efficient heat dissipation may be achieved.

According to example embodiments, an electrical appliance includes a circuit board which is populated with a heat-generating component, e.g., a power semiconductor, a heat sink having at least one cooling fin and a housing part. A bushing, e.g., a press-fit bushing, is plugged into a recess in the cooling fin, a screw, the screw head of which presses the printed circuit board, together with the component, towards the heat sink, is screwed into an internal thread of the bushing, and the bushing has a polyhedral region which is pressed into the housing part. For example, the screw axis of the screw and/or the thread axis of the internal thread is oriented perpendicular to the direction of extension of the cooling fin. For example, the bushing is made of steel, the housing part is made of aluminum or steel, and the cooling fin is made of aluminum.

For example, the bushing forms a press fit with the cooling fin, and the bushing also forms a press fit with the housing part.

An advantage of this is that, on the one hand, the bushing is firmly connected to the housing part, and, on the other hand, when screwed into the bushing, the screw positions and/or presses the bushing against a step of the heat sink. This presses the printed circuit board with the component against the heat sink and improves and ensures heat transfer. At the same time, the screw together with the press-in nut is arranged as an electrical ground connection for the housing part in order to connect it to a conductive path on the printed circuit board.

To increase the safety of the electrical ground connection, the connection may optionally be implemented as a double connection and thus more securely.

According to example embodiments, the bushing has a toothing which is cut into the material of the cooling fin, and, for example, the recess is a blind hole and the toothing is cut into the material of the cooling fin at the base of the blind hole. The heat sink is thus also electrically securely connected to the socket and thus also to the screw and the housing part, and is grounded, and a PE connection can also be implemented instead of the ground connection.

According to example embodiments, the toothing is an external toothing. An advantage of this is that the toothing cuts into the recess of the heat sink.

According to example embodiments, the screw projects through the heat sink, e.g., through the cooling fin. An advantage of this is that there is an electrical connection between the printed circuit board and the housing part.

According to example embodiments, the housing part is arranged on the side of the heat sink facing away from the printed circuit board and/or the printed circuit board is arranged on the side of the heat sink facing away from the housing part.

An advantage of this is that the housing part can be electrically connected via the screw to a conductive path of the printed circuit board, which can be arranged on the other side of the heat sink in a mechanically protected manner.

According to example embodiments, the housing part is made as a punched and bent part from a metal sheet. An advantage of this is that ready production is possible.

According to example embodiments, the polyhedral region is arranged flush with the housing part on at least one side of the housing part, e.g., on the side of the housing part facing away from the heat sink.

According to example embodiments, the polyhedral region projects radially from the bushing. An advantage of this is that a high level of rotational safety can be achieved.

According to example embodiments, the polyhedral region is spaced from the toothing. An advantage of this is that the housing part is spaced from a step of the receiving region of the printed circuit board against which the bushing is positioned.

According to example embodiments, the recess is an interruption in the cooling fin. An advantage of this is that the cooling fin has a thickened region in which a bore is provided as a recess.

According to example embodiments, the bushing is made of steel. An advantage of this is that ready, cost-effective production is possible.

According to example embodiments, the heat sink is made of aluminum. An advantage of this is that the bushing cuts readily into the material of the heat sink.

According to example embodiments, the cooling fin has a thickening which is interrupted via the recess, e.g., the bushing is plugged into the recess and is thus received in the thickening. An advantage of this is that receiving the socket is ready and safe.

According to example embodiments, a further bushing, e.g., a further press-fit bushing, is plugged into a further recess of a further cooling fin of the heat sink, a further screw, the screw head of which presses the printed circuit board, together with a further component, towards the heat sink, is screwed into an internal thread of the further bushing, the further bushing has a further polyhedral region which is also pressed into the housing part, the further bushing has a further toothing which is cut into the material of the further cooling fin, the further toothing is also an external toothing, and the further screw projects through the heat sink, e.g., through the further cooling fin. An advantage of this is that a sufficiently secure ground connection can be established. This is because the two screws act as an independently functioning electrical ground line or PE line. If one of the screws fails, the respective other screw ensures that the function is maintained.

According to example embodiments, the bushings, e.g., via their cylindrical outer circumference, align the housing part in a form-fitting manner relative to the heat sink. An advantage of this is that the housing part is oriented towards the line connecting the two bushings and that the cylindrical outer shape of the bushings ensures high-precision centering of the housing part towards the bushings.

Further features and aspects of example embodiments of the present invention are explained in more detail below with reference to the appended schematic Figures.

### BRIEF DESCRIPTION OF THE DRAWINGS

FIG. 1 is a cross-sectional view through a region of an electrical appliance, in which a bushing 1 is used.

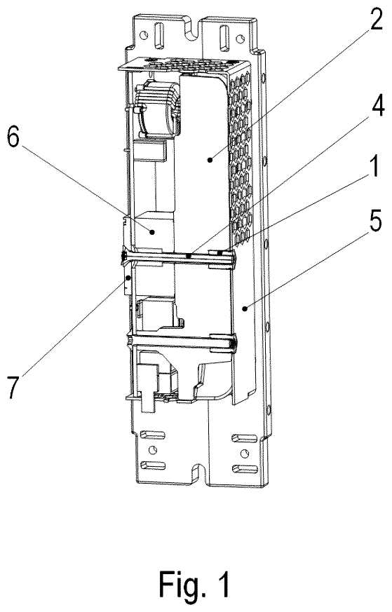

FIG. 2 is a perspective view of a region of the electrical appliance.

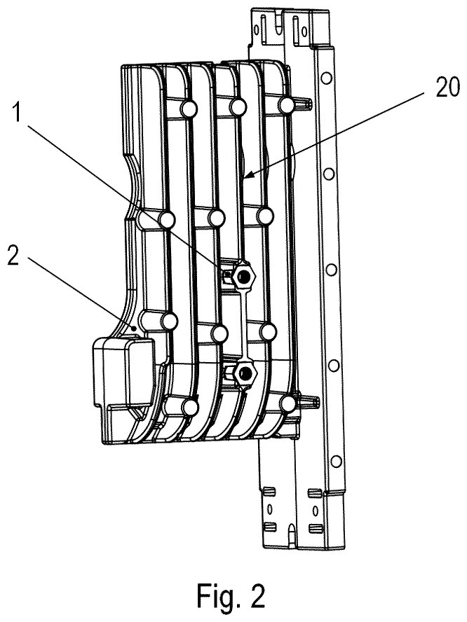

FIG. 3 is a perspective view of the bushing 1.

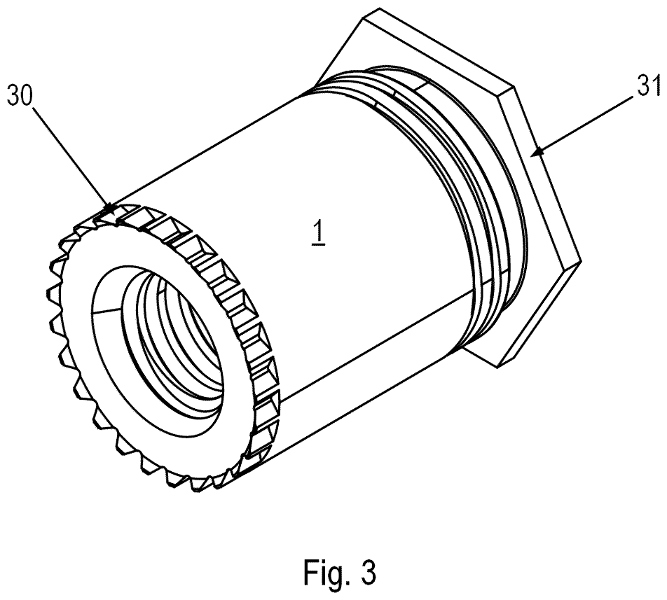

FIG. 4 illustrates the connection of the bushing 1 to a housing part 5 of the electrical appliance.

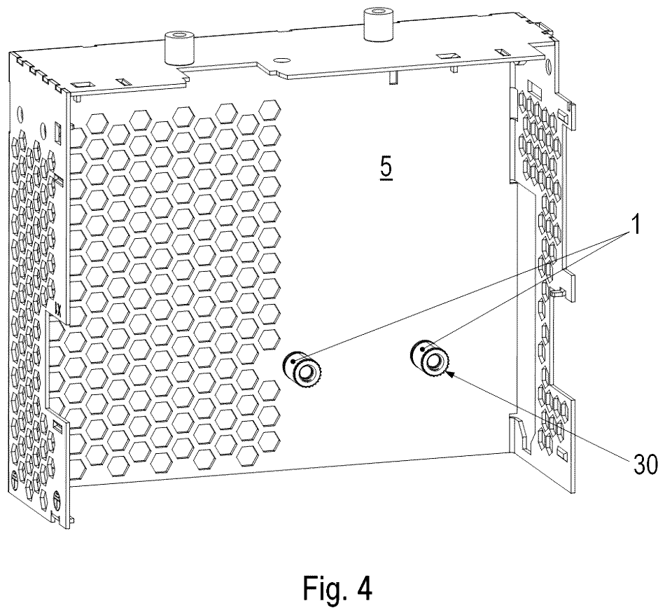

### DETAILED DESCRIPTION

As illustrated in the Figures, the electrical appliance has a printed circuit board 3, which is pressed towards a heat sink 2 by the screw head of a screw 4.

Thus, a heat-generating component, e. g., a power semiconductor component, mounted on the printed circuit board 3 is pressed against the heat sink 2, e.g., to improve the thermal coupling of the component to the heat sink 2.

The bushing 1 is, for example, arranged as a press-fit bushing.

The bushing 1 is plugged into a recess, e.g., an interruption, of a cooling fin 20 of the heat sink 2 and has an internal thread into which a threaded section of the screw 4 is screwed, and the bushing 1 is supported in the cooling fin 20 at a step of the cooling fin 20.

The bushing 1 has a polyhedral region 31, e.g., a hexagonal region, which projects from the cooling fin 20 and is pressed into a housing part 5 made of metal sheet. Thus, the bushing 1 is embedded in the housing part 5 for conjoint rotation and connected for conjoint rotation with the housing part 5.

At the end region of the bushing 1 facing away from the polyhedral region 31, the bushing 1 has a toothing 30 with which the bushing 1 is plugged into the cooling fin 20 such that the toothing 30 is cut into the material of the cooling fin 20.

The heat sink 2 together with the cooling fin 20 is, for example, made of aluminum; the bushing 1 is, for example, made of steel.

The metal sheet of the housing part 5 is, for example, made of sheet steel. For example, the housing part 5 is arranged as a punched and bent part.

The toothing 30 is arranged as external toothing.

The housing part 5 is, for example, arranged on the side of the heat sink 2 facing away from the printed circuit board 3. The housing part 5 is detachably connected to the heat sink.

A pressure plate 7 is arranged between the screw head and the printed circuit board 3 so that the force flow introduced by the screw 4 is spread out and thus the printed circuit board 3 is protected against excessive pressure. The pressure plate 7 is, for example, made of metal so that the housing part 5 is electrically connected to a conductive path of the printed circuit board 3 via the metal bushing 1 and the metal screw 4 as well as the metal pressure plate 7. In this manner, a ground connection and/or PE connection can be provided for the housing part 5.

The screw axis of the screw 4 is oriented perpendicular to the direction in which the cooling fin 20 extends.

For example, the electrical appliance is a converter that feeds an electric motor and thus controls or regulates its speed or torque. Not only the signal electronics, which generate control signals for the component, e.g., the power semiconductor, but also the power electronics of the converter, which include the component, e. g., the power semiconductor, are arranged on the printed circuit board.

According to example embodiments, the component is a power module including multiple power semiconductors.

### LIST OF REFERENCE NUMERALS

1 Bushing, e.g., press-fit bushing
2 Heat sink
3 Printed circuit board
4 Screw
5 Housing part
6 Heat-generating component
7 Pressure plate
20 Cooling fin
30 Toothing
31 Polyhedral region, e. g., hexagonal region

1-15. (canceled)

16. An electrical appliance, comprising:
a printed circuit board populated with a heat-generating component;
a heat sink having at least one cooling fin;
a housing part;
a bushing arranged in a recess in the cooling fin and including a polyhedral region pressed into the housing part; and
a screw screwed into an internal thread of the bushing and including a screw head that presses the printed circuit board, together with the component, toward the heat sink.

17. The electrical appliance according to claim 16, wherein the electrical appliance is arranged as a converter configured to feed an electric motor.

18. The electrical appliance according to claim 16, wherein the heat-generating component includes a power semiconductor, the bushing is arranged as a press-fit bushing.

19. The electrical appliance according to claim 16, wherein the bushing forms a press fit with the cooling fin and with the housing part, the recess is arranged in a thickening of the cooling fin, a screw axis of the screw and/or a thread axis of the internal thread is oriented perpendicular to a direction of extension of the cooling fin, the bushing is made of steel, the housing part is made of aluminum or steel, and the cooling fin is made of aluminum.

20. The electrical appliance according to claim 16, wherein the bushing includes a toothing that cuts into a material of the cooling fin.

21. The electrical appliance according to claim 20, wherein the recess includes a blind hole, and the toothing cuts into the material of the cooling fin at a base of the blind hole.

22. The electrical appliance according to claim 20, wherein the toothing includes an external toothing.

23. The electrical appliance according to claim 16, wherein the screw projects through the heat sink and/or through the cooling fin.

24. The electrical appliance according to claim 16, wherein the housing part is arranged on a side of the heat sink facing away from the printed circuit board.

25. The electrical appliance according to claim 16, wherein the printed circuit board is arranged on a side of the heat sink facing away from the housing part.

26. The electrical appliance according to claim 16, wherein the housing part is arranged as a punched and bent part of a metal sheet.

27. The electrical appliance according to claim 16, wherein the polyhedral region is arranged flush with the housing part on at least one side of the housing part and/or on a side of the housing part facing away from the heat sink.

28. The electrical appliance according to claim 16, wherein the polyhedral region projects radially from the bushing.

29. The electrical appliance according to claim 16, wherein the polyhedral region is spaced from the toothing.

30. The electrical appliance according to claim 16, wherein the recess is arranged as an interruption in the cooling fin.

31. The electrical appliance according to claim 16, wherein the bushing is made of steel.

32. The electrical appliance according to claim 16, wherein the heat sink is made of aluminum.

33. The electrical appliance according to claim 16, wherein the cooling fin includes a thickening that is interrupted by the recess.

34. The electrical appliance according to claim 33, wherein the bushing is arranged in the recess and is received in the thickening.

35. The electrical appliance according to claim 16, wherein a further bushing is arranged in a further recess of a further cooling fin of the heat sink, a further screw is screwed into an internal thread of the further bushing and includes a screw head that presses the printed circuit board, together with a further component, toward the heat sink, the further bushing includes a further polyhedral region that is pressed into the housing part, the further bushing includes a further toothing that cuts into a material of the further cooling fin, the further toothing includes an external toothing, and the further screw projects through the heat sink and/or through the further cooling fin.

36. The electrical appliance according to claim 35, wherein the bushings align the housing part in a form-fitting manner relative to the heat sink.
